(19) United States
(12) Patent Application Publication
(10) Pub. No.: US 2022/0077232 A1
(43) Pub. Date: Mar. 10, 2022

(54) INTEGRATED STRUCTURE OF AND INTEGRATED METHOD FOR CRYSTAL RESONATOR AND CONTROL CIRCUIT

(71) Applicant: NINGBO SEMCONDUCTOR INTERNATIONAL CORPORATION (SHANGHAI BRANCH), Shanghai (CN)

(72) Inventor: Xiaoshan QIN, Zhejiang (CN)

(21) Appl. No.: 17/419,660

(22) PCT Filed: Nov. 5, 2019
(86) PCT No.: PCT/CN2019/115651

§ 371 Date: Jun. 29, 2021

(30) Foreign Application Priority Data
Dec. 29, 2018 (CN) 201811643071.8

(51) Int. Cl. H01L 27/20; H03H 3/02; H03H 9/05; H03H 9/10; H03H 9/19

(52) U.S. Cl. CPC H01L 27/20; H03H 3/02; H03H 9/19; H03H 9/1042; H03H 9/0547

(57) ABSTRACT

A structure and method for integrating a crystal resonator with a control circuit are disclosed. The resonator is formed by forming a lower cavity (120) in the device wafer (100) containing the control circuit (110) and a piezoelectric vibrator (200) on a front side (100U) of the device wafer (100) and by fabricating a cap layer (420) using planar fabrication processes, which encloses the piezoelectric vibrator (200) within an upper cavity (400). In addition, a semiconductor die (500) may be bonded to a back side (100D) of the device wafer (100), helping in additionally increasing the integration of the crystal resonator and allowing on-chip modulation of the crystal resonator's parameters. In this way, in addition to being able to integrate with other semiconductor components more easily with a higher degree of integration, the crystal resonator is more compact in size and less power-consuming.

### TECHNICAL FIELD

The present invention relates to the field of semiconductor technology and, in particular, to a structure and method for integrating a crystal resonator with a control circuit.

### BACKGROUND

A crystal resonator is a device operating on the basis of inverse piezoelectricity of a piezoelectric crystal. As key components of crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, existing crystal resonators are not only hard to be integrated with other semiconductor components and bulky themselves.

For example, common existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated integrated circuit by soldering or gluing additionally hinders the crystal resonators' miniaturization.

### SUMMARY OF THE INVENTION

It is an objective of the present invention to provide a method for integrating a crystal resonator with a control circuit, which overcomes the above described problems with conventional crystal resonators, i.e., a bulky size and difficult integration.

According to the present invention, the above object is attained by a method for integrating a crystal resonator with a control circuit, including:

providing a device wafer having the control circuit formed therein;

forming a lower cavity of the crystal resonator in the device wafer by etching the device wafer from a front side thereof;

forming a piezoelectric vibrator including a top electrode, a piezoelectric crystal and a bottom electrode on the front side of the device wafer above the lower cavity and forming a first connecting structure electrically connecting the top and bottom electrodes of the piezoelectric vibrator to the control circuit;

forming a cap layer on the front side of the device wafer, the cap layer hooding the piezoelectric vibrator and delimiting an upper cavity of the crystal resonator together with the piezoelectric vibrator and the device wafer; and

bonding a semiconductor die to a back side of the device wafer and forming a second connecting structure electrically connecting the semiconductor die to the control circuit.

It is another objective of the present invention to provide a structure for integrating a crystal resonator with a control circuit, including:

a device wafer, in which the control circuit and a lower cavity are formed, the lower cavity exposed from a front side of the device wafer;

a piezoelectric vibrator including a top electrode, a piezoelectric crystal and a bottom electrode, the piezoelectric vibrator formed on the front side of the device wafer and aligned with the lower cavity;

a first connecting structure configured to electrically connect the top and bottom electrodes of the piezoelectric vibrator to the control circuit;

a cap layer formed on the front side of the device wafer, the cap layer hooding the piezoelectric vibrator and delimiting an upper cavity together with the piezoelectric vibrator and the device wafer;

a semiconductor die bonded to a back side of the device wafer; and

a second connecting structure configured to electrically connect the semiconductor die to the control circuit.

In the provided method, integration of the control circuit and the crystal resonator is achieved on a single device wafer by utilizing planar fabrication processes to form the lower cavity in the device wafer containing the control circuit, the piezoelectric vibrator on the front side of the device wafer, and the cap layer enclosing the piezoelectric vibrator within the upper cavity. Additionally, the semiconductor die can be further bonded to the back side of the device wafer, resulting in an enhancement in performance of the crystal resonator by allowing on-chip modulation of its parameters (e.g., in order to correct raw deviations of the crystal resonator such as temperature and frequency drifts), in addition to a significant increase in the crystal resonator's degree of integration.

Therefore, compared with traditional crystal resonators (e.g., surface-mount ones), in addition to being able to integrate with other semiconductor components with a higher degree of integration, the crystal resonator of the present invention is more compact, miniaturized in size, less costly and less power-consuming.

### BRIEF DESCRIPTION OF THE DRAWINGS

FIG. 1 shows a flowchart schematically illustrating a method for integrating a crystal resonator according to an embodiment of the present invention.

FIGS. 2a to 2m are schematic representations of structures resulting from steps in the method according to an embodiment of the present invention.

In these figures,

100—device wafer; AA—device area; 100U—front side; 100D—back side; 100A—substrate wafer; 100B—dielectric layer; 110—control circuit; 111—first circuit; 111a—first interconnect; 111b—third interconnect; 112—second circuit; 112a—second interconnect; 112b—fourth interconnect; 120—lower cavity; 200—piezoelectric vibrator; 210—bottom electrode; 220—piezoelectric crystal; 230—top electrode; 300—plastic encapsulation layer; 300a—through hole; 310—third conductive plug; 320—interconnecting wire; 400—upper cavity; 410—sacrificial layer; 420—cap layer; 420a—opening; 430—closure plug; 500—semiconductor die; 511—first connecting wire; 512—second connecting wire; 521—first conductive plug; 522—second conductive plug; 531—first lead—out wire; 532—second lead—out wire; 540—isolating dielectric layer; 551—first contact plug; 552—second contact plug; 610—first plastic encapsulation layer; 620—second plastic encapsulation layer.

### DETAILED DESCRIPTION

The core idea of the present invention is to provide a structure and method for integrating a crystal resonator with a control circuit, in which planar fabrication processes are utilized to integrate the crystal resonator and an associated semiconductor die both on a device wafer where the control circuit is formed. This, on the one hand, results in a size reduction of the crystal resonator and, on the other hand, allows an increased degree of integration of the crystal resonator with other semiconductor components.

Specific embodiments of the proposed structure and method will be described below in greater detail with reference to the accompanying drawings. Features and advantages of the invention will be more apparent from the following description. Note that the accompanying drawings are provided in a very simplified form not necessarily drawn to exact scale and for the only purpose of helping to explain the disclosed embodiments in a more convenient and clearer way.

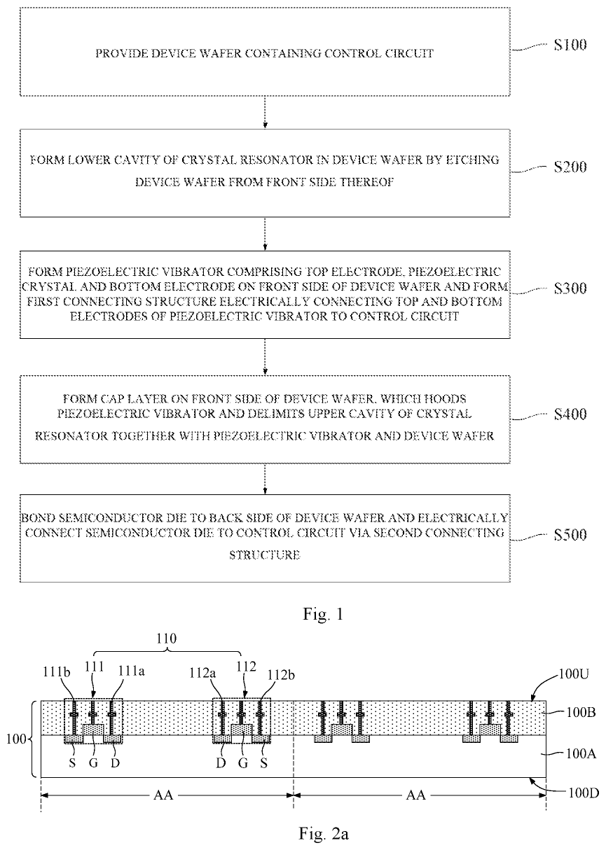

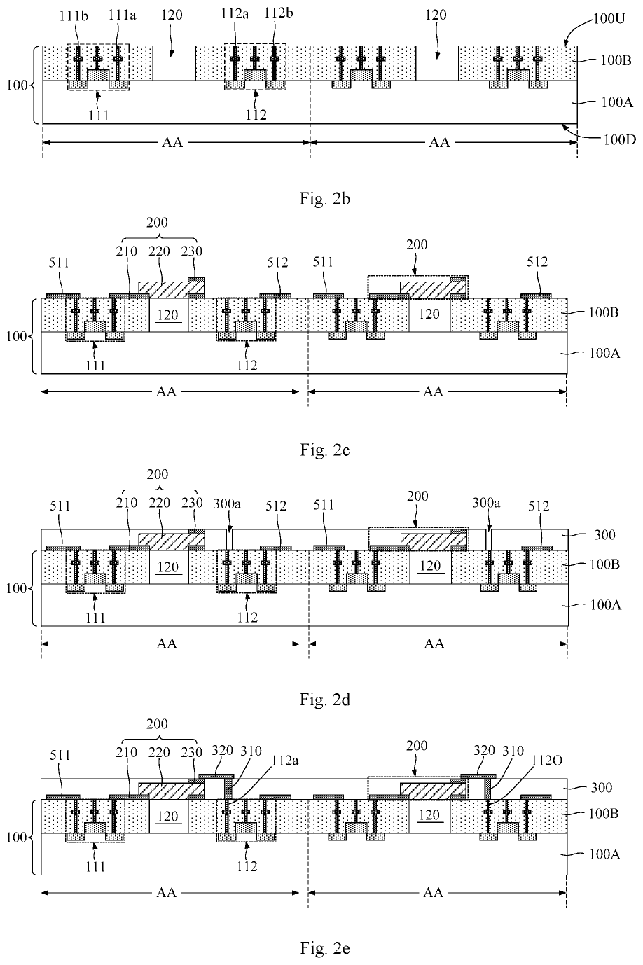

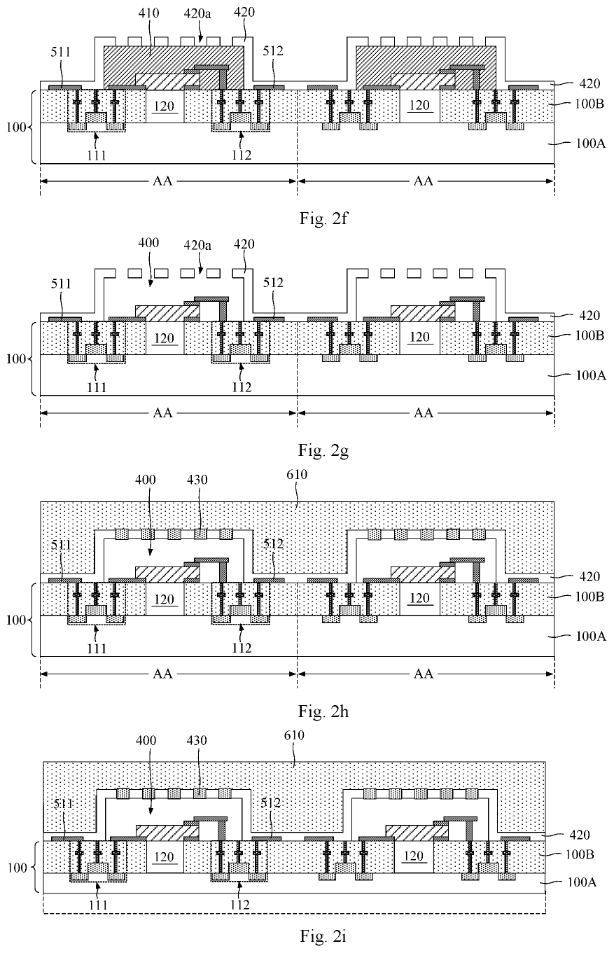

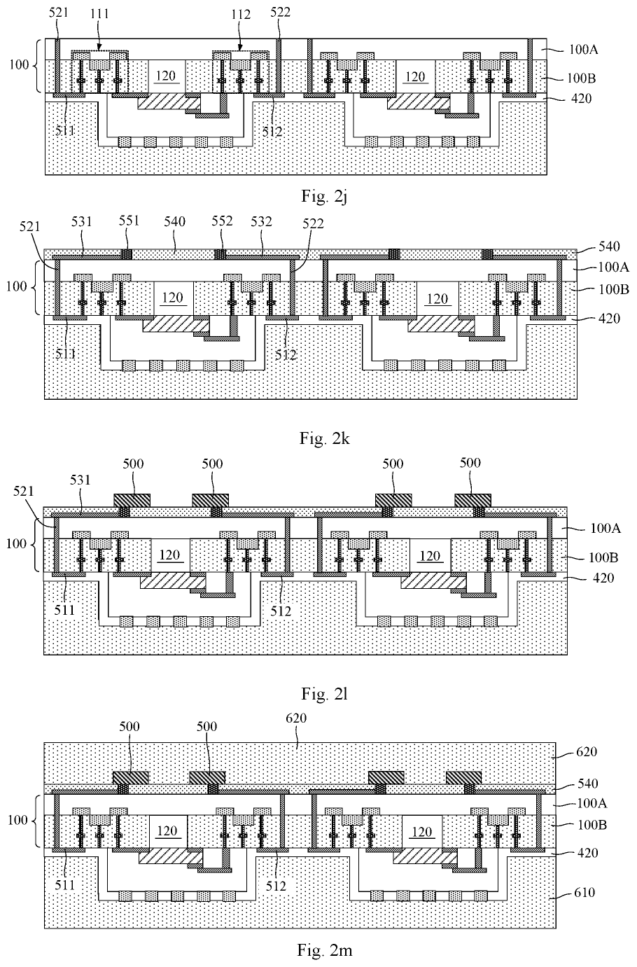

FIG. 1 shows a flowchart schematically illustrating a method for integrating a crystal resonator according to an embodiment of the present invention, and FIGS. 2a to 2k are schematic representations of structures resulting from steps in the method according to an embodiment of the present invention. In the following, steps for forming the crystal resonator will be described in detail with reference to the figures.

In step S100, with reference to FIG. 2a, a device wafer 100 is provided, and a control circuit 110 is formed in the device wafer 100.

Specifically, the device wafer 100 has a front side 100U and a back side 100D opposite to the front side, and the control circuit 110 includes a plurality of interconnects, at least some of which extend to the front side of the device wafer. The control circuit 110 may be adapted to, for example, apply an electrical signal to a subsequently formed piezoelectric vibrator.

A plurality of crystal resonators may be formed on the single device wafer 100. Accordingly, there may be a plurality of device areas AA defined on the device wafer 100, with the control circuit 110 being formed in one of the device areas AA.

The control circuit 110 may include a first circuit 111 and a second circuit 112, the first circuit 111 and the second circuit 112 may be electrically connected to a top electrode and a bottom electrode of the subsequently formed piezoelectric vibrator, respectively.

With continued reference to FIG. 2a, the first circuit 111 may include a first transistor, a first interconnect 111a and a third interconnect 111b. The first transistor may be buried within the device wafer 100, and the first and third interconnect 111a, 111b may be both connected to the first transistor and extend to the front side of the device wafer 100. For example, the first interconnect 111a may be connected to a drain of the first transistor, and the third interconnect 111b to a source of the first transistor.

Similarly, the second circuit 112 may include a second transistor, a second interconnect 112a and a fourth interconnect 112b. The second transistor may be buried within the device wafer 100, and the second and fourth interconnects 112a, 112b may be both connected to the second transistor and extend to the front side of the device wafer 100. For example, the second interconnect 112a may be connected to a drain of the second transistor, and the fourth interconnect 112b may be connected to a source of the second transistor.

In this embodiment, the device wafer 100 includes a substrate wafer 100A and a dielectric layer 100B on the substrate wafer 100A. Additionally, the first and second transistors may be both formed on the substrate wafer 100A and covered by the dielectric layer 100B. The third, first, second and fourth interconnects 111b, 111a, 112a, 112b may be all formed within the dielectric layer 100B and extend to a surface of the dielectric layer 100B facing away from the substrate wafer.

The substrate wafer 100A may be either a silicon wafer or a silicon-on-insulator (SOI) wafer. In the case of the substrate wafer 100A being an SOI wafer, the substrate wafer may include a base layer 101, a buried oxide layer 102 and a top silicon layer 103 stacked in sequence from the back side 100D to the front side 100U.

In step S200, with reference to FIG. 2b, a lower cavity 120 of the crystal resonator is formed by etching the device wafer 100 from the front side thereof. Specifically, the lower cavity 120 may be exposed at the front side 100U of the device wafer and the lower cavity 120 may be configured, for example, to provide a space in which the subsequently formed piezoelectric vibrator can vibrate.

In this embodiment, the lower cavity 120 is formed in the dielectric layer 100B of the device wafer. In each device area AA, such a lower cavity 120 may be formed. A method for forming the lower cavity 120 may include etching the dielectric layer 100B until the substrate wafer 100A is reached. In this manner, the lower cavity 120 may be formed in the dielectric layer 100B. The lower cavity 120 may have a depth that is determined, without limitation, as practically required. For example, the lower cavity 120 may either extend only in the dielectric layer 100B or further into the substrate wafer 100A from the dielectric layer 100B.

It is to be noted that the relative positions of the lower cavity 120 and the first and second circuits shown in the figures are merely for illustration, and in practice, the arrangement of the first and second circuits may depend on the actual circuit layout requirements. The present invention is not limited in this regard.

As noted above, the substrate wafer 100A may be implemented as an SOI wafer. In the case of the substrate wafer 100A being an SOI wafer, the etching process for forming the lower cavity may proceed further through a top silicon layer of the SOI wafer so that the formed lower cavity extends from the dielectric layer down to an underlying buried oxide layer of the wafer.

In step S300, with reference to FIGS. 2c to 2e, a piezoelectric vibrator 200 including a top electrode 230, a piezoelectric crystal 220 and a bottom electrode 210 is formed on the front side of the device wafer 100, with the peripheral edge portions of the piezoelectric vibrator 200 residing on top edges of the lower cavity 120, thus aligning the piezoelectric vibrator 200 with the lower cavity 120. In addition, a first connecting structure is formed, which electrically connects both the top and bottom electrodes 230, 210 of the piezoelectric vibrator to the control circuit.

In this embodiment, the bottom electrode 210 is electrically connected to the first circuit 111 (more exactly, the bottom electrode 210 is electrically connected to the first interconnect 111a) and the top electrode 230 to the second circuit 112 (more exactly, the top electrode 230 is electrically connected to the second interconnect 112a). As such, an electrical signal can be applied by the control circuit 110 to the piezoelectric vibrator 200 to create an electric field in the piezoelectric vibrator 200, which causes the piezoelectric vibrator 200 to change its shape. The magnitude of the shape change of the piezoelectric vibrator 200 depends on the strength of the electric field, and when the electric field in the piezoelectric vibrator 200 is inverted, the piezoelectric vibrator 200 will change its shape in the opposite direction. Therefore, when the control circuit 110 applies an AC signal to the piezoelectric vibrator 200, the piezoelectric crystal 520 will change shape alternately in opposite directions and thus alternately contract and expand due to oscillations of the electric field. As a result, the piezoelectric vibrator 200 will vibrate mechanically.

Specifically, the formation of the piezoelectric vibrator 200 may include, for example, the following steps:

Step 1: With reference to FIG. 2c, form the bottom electrode 210 at a predetermined location on the front side 100U of the device wafer 100. In this embodiment, the bottom electrode 210 surrounds the lower cavity 120 and is electrically connected to the first interconnect 111a in the first circuit 111 and thus the bottom electrode 210 is electrically connected to the first transistor via the first interconnect 111a. This enables the first transistor to control an electrical signal applied to the bottom electrode 210.

Notably, in this embodiment, the bottom electrode 210 covers the first interconnect 111a but not the third interconnect 111b. The bottom electrode 210 also does not cover the fourth interconnect 112b and second interconnect 112a.

The bottom electrode 210 may be formed of, for example, silver, and the formation may involve successive processes of thin-film deposition, photolithography and etching. Alternatively, the bottom electrode 210 may be formed using a vapor deposition process.

Step 2: With continued reference to FIG. 2c, bond the piezoelectric crystal 220 to the bottom electrode 210 so that the piezoelectric crystal 220 is located above the lower cavity 120. Specifically, the piezoelectric crystal 220 is disposed on the bottom electrode 210 with its peripheral edge portions residing on top edges of the lower cavity 120. The piezoelectric crystal 220 may be, for example, a quartz crystal plate.

Step 3: With continued reference to FIG. 2c, form the top electrode 230 on the piezoelectric crystal 220. Like the case of the bottom electrode 210, the top electrode 230 may also be formed of, for example, silver, using a vapor deposition process or thin-film deposition process.

Notably, in this embodiment, the bottom electrode 210, the piezoelectric crystal 220 and the top electrode 230 are successively formed over the device wafer 100 using semiconductor processes. However, in other embodiments, it is also possible to form the top and bottom electrodes on opposing sides of the piezoelectric crystal and then bond the three as a whole onto the device wafer.

As noted above, in the resulting piezoelectric vibrator 200, the top and bottom electrodes 230, 210 are electrically connected to the second and first interconnects 112a, 111a, respectively, by the first connecting structure.

Specifically, the first connecting structure may include a first connection and a second connection. The first connection may connect the first interconnect 111a to the bottom electrode 210 of the piezoelectric vibrator, and the second connection may connect the second interconnect 112a to the top electrode 230 of the piezoelectric vibrator.

In this embodiment, the bottom electrode 210 is disposed on the front side of the device wafer 100 and under the piezoelectric crystal 220 and has an extension extending beyond the piezoelectric crystal 220 over the first interconnect 111a. Therefore, it can be considered that the extension of the bottom electrode 210 from the piezoelectric crystal provides the first connection.

Of course, in alternative embodiments, the first connection may be formed on the device wafer 100 and electrically connected to the first interconnect prior to the formation of the bottom electrode, and may be brought into electrical connection with the bottom electrode 210 subsequent to the formation of the bottom electrode 210. In such embodiments, the first connection may include, for example, a rewiring layer connected to the first interconnect. Additionally, subsequent to the formation of the bottom electrode on the device wafer, the rewiring layer may be further electrically connected to the bottom electrode 210.

Further, subsequent to the formation of the top electrode 230, the second connection may be formed to electrically connect the top electrode 230 to the second interconnect 112a. The second connection may be comprised of an interconnecting wire and a conductive plug (e.g., a third conductive plug). The third conductive plug may be connected to the second interconnect 112a at the bottom and to one end of the interconnecting wire at the other end, and the other end of the interconnecting wire may cover at least part of, and thus come into connection with, the top electrode 230. Specifically, the formation of the second connection may include the steps detailed below.

At first, with reference to FIG. 2d, a plastic encapsulation layer 300 is formed on the front side of the device wafer 100. The plastic encapsulation layer 300 covers the piezoelectric crystal 220, while the top electrode 230 is exposed therefrom. Exemplary materials for the plastic encapsulation layer 300 may include polyimide.

Next, with continued reference to FIG. 2d, a through hole 300a is formed in the plastic encapsulation layer 300. The through hole 300a extends through the plastic encapsulation layer 300 so that the second interconnect 112a is exposed therein.

Subsequently, with reference to FIG. 2e, a conductive material is filled in the through hole 300a, resulting in the formation of a conductive plug 310 (e.g., the third conductive plug 310), which is electrically connected to the second interconnect 112a at the bottom and exposed from the plastic encapsulation layer 300 at the top.

Afterward, with continued reference to FIG. 2e, an interconnecting wire 320 is formed on the plastic encapsulation layer 300, followed by removal of the plastic encapsulation layer. The interconnecting wire 320 is electrically connected to the top electrode 230 at one end and to the third conductive plug 310 at the other end so that the top electrode 230 is connected to the second interconnect 112a in the second circuit 112 via both the interconnecting wire 320 and the third conductive plug 310.

Of course, in alternative embodiments, the top electrode may be so formed on the piezoelectric crystal as to have an extension extending beyond the piezoelectric crystal. In this case, the third conductive plug of the second connection may be so formed under the extension of the top electrode that it is connected to the second interconnect at the bottom and connected to, and thus provides support for, the extension of the top electrode at the top.

Alternatively, the third conductive plug of the second connection may be formed prior to the formation of the top electrode. Specifically, the formation of the top electrode and the third conductive plug of the second connection may include the steps detailed below.

At first, a plastic encapsulation layer is formed on the device wafer 100. In this embodiment, the plastic encapsulation layer covers the device wafer 100, with the piezoelectric crystal 220 being exposed therefrom.

Next, a through hole is formed in the plastic encapsulation layer and a conductive material is filled in the through hole, resulting in the formation of the third conductive plug, which is electrically connected to the second interconnect 112a.

Afterward, the top electrode is so formed on the piezoelectric crystal 220 that it covers at least part of the piezoelectric crystal 220 and extends beyond it over the third conductive plug. As a result, the top electrode is electrically connected to the second interconnect 112a via the third conductive plug.

In step S400, with reference to FIGS. 2f to 2g, a cap layer 420 is formed on the front side of the device wafer 100, the cap layer 420 hoods the piezoelectric vibrator 200 and delimits an upper cavity 400 of the crystal resonator together with the piezoelectric vibrator 200 and the device wafer.

In this way, the piezoelectric vibrator 200 is enclosed in the upper cavity 400 and can vibrate in the lower and upper cavities 120, 400.

Specifically, the formation of the cap layer 420 that delimits the upper cavity 400 may include, for example, the steps detailed below.

In a first step, with reference to FIG. 2f, a sacrificial layer 410 is formed on the surface of the device wafer 100, the sacrificial layer 410 covers the piezoelectric vibrator 200.

In a second step, with continued reference to FIG. 2f, a cap material layer is formed over the surface of the device wafer 100, which wraps the sacrificial layer 410 by covering its top and side surfaces. In this embodiment, the cap material layer also covers the surface of the device wafer.

The space occupied by the sacrificial layer 410 corresponds to the internal space of the subsequently formed upper cavity. Therefore, a depth of the resulting upper cavity may be adjusted by changing a height of the sacrificial layer. It will be recognized that the depth of the upper cavity may be determined as practically required, and the present invention is not limited in this regard.

In a third step, with reference to FIG. 2g, at least one opening 420a is formed in the cap material layer, thus resulting in the formation of the cap layer 420. The sacrificial layer 410 is exposed in the opening 420a.

In a fourth step, with continued reference to FIG. 2g, the sacrificial layer 410 is removed via the opening 420a, resulting in the formation of the upper cavity 400.

Optionally, with reference to FIG. 2h, the method may further include closing the opening in the cap layer 420, thus enclosing the piezoelectric vibrator within the upper cavity 400. Specifically, the enclosure of the upper cavity 400 can be accomplished by closing the opening with a closure plug 430.

With continued reference to FIG. 2h, subsequent to the closure of the cap layer 420, the method may further include forming a first plastic encapsulation layer 610 over the front side 100U of the device wafer 100, the first plastic encapsulation layer 610 covers and protects all the structures formed on the front side of the device wafer (including an external surface of the cap layer outside the upper cavity, as well as a first wiring layer).

In step S500, with reference to FIGS. 2i to 2l, a semiconductor die is bonded to the back side of the device wafer in such a manner that it is electrically connected to the control circuit by a second connecting structure.

In the semiconductor die, for example, a drive circuit for providing an electrical signal may be formed. The electrical signal is applied by the control circuit to the piezoelectric vibrator 200 so as to control shape change thereof.

Specifically, the second connecting structure may include conductive plugs and connecting wires. In this case, for example, the connecting wires and conductive plugs may lead connection ports of the control circuit from the front to back side of the device wafer.

A method for forming the second connecting structure may include, for example, the steps detailed below.

First of all, with reference to FIG. 2c, the connecting wires are formed on the front side of the device wafer 100, which are electrically connected to the control circuit. In this embodiment, a first connecting wire 511 electrically connected to the third interconnect 111b and a second connecting wire 512 electrically connected to the fourth interconnect 112b are formed on the front side of the device wafer 100.

Next, with reference to FIG. 2j, the device wafer 100 is etched from the back side so that connecting holes are formed, which extend through the device wafer 100, and in which the respective connecting wires are exposed. In this embodiment, the connecting holes include a first connecting hole and a second connecting hole, in which the first connecting wire 511 and the second connecting wire 512 are exposed, respectively.

In addition, referring to FIG. 2i, before the first and second connecting holes are formed by etching the device wafer, the device wafer 100 may be thinned from the back side thereof. In this way, the first and second connecting holes formed may each have a reduced depth, which facilitates maintaining a desired morphology of the connecting holes.

Subsequently, with reference to FIG. 2j, a conductive material is filled in the connecting holes, resulting in the formation of the conductive plugs. One end of each conductive plug is connected to a corresponding one of the connecting wires, and the other end is reserved for subsequent electrical connection with the semiconductor die.

In this embodiment, a first conductive plug 521 and a second conductive plug 522 are formed. One end of the first conductive plug 521 is connected to the first connecting wire 511, and the other end of the first conductive plug 521 is reserved for subsequent electrical connection with the semiconductor die 500. One end of the second conductive plug 522 is connected to the second connecting wire 512, and the other end of the second conductive plug 522 is reserved for subsequent electrical connection with the semiconductor die 500.

It is to be noted that, in this embodiment, during the formation of the second connecting structure, the formation of the conductive plugs follows the formation of the connecting wires and occurs on the etched back side of the device wafer 100. However, in alternative embodiments, the formation of the conductive plugs may also precede the formation of the connecting wires and occur on the front side of the device wafer.

In such embodiments, the formation of the second connecting structure may include, for example, the steps detailed below.

At first, the device wafer 100 is etched from the front side to form connecting holes therein. In this embodiment, the connecting holes (which may similarly include a first connecting hole and a second connecting hole) are formed prior to the formation of the first plastic encapsulation layer by etching the device wafer.

Next, the conductive plugs are formed by filling a conductive material in the connecting holes. In this embodiment, the first and second conductive plugs 521, 522 are formed.

Subsequently, the connecting wires connecting the respective connecting plugs to the control circuit are formed on the front side of the device wafer. In this embodiment, the connecting wires include a first connecting wire 511 and a second connecting wire 512. The first connecting wire 511 connects the first conductive plug 521 to the third interconnect 111b and the second connecting wire 512 connects the second conductive plug 522 to the fourth interconnect 112b.

Afterward, the device wafer 100 is thinned from the back side until the conductive plugs are exposed. In this embodiment, the first and the second conductive plugs 521, 522 are exposed and become ready for electrical connection with the semiconductor die 500. In case of the first and second conductive plugs penetrating through the device wafer, this thinning step may be omitted.

Optionally, the formation of the second connecting structure may further include the steps detailed below.

At first, with reference to FIG. 2k, lead-out wires are formed on the back side of the device wafer 100, which cover the respective conductive plugs. In this embodiment, the lead-out wires include a first lead-out wire 531 and a second lead-out wire 532, the first lead-out wire 531 covers the first conductive plug 521 and the second lead-out wire 532 covers the second conductive plug 522.

Next, with continued reference to FIG. 2k, a plastic encapsulation layer 540 is formed over the back side of the device wafer 100, the plastic encapsulation layer 540 covers the first and second lead-out wires 531, 532.

Subsequently, contact holes are formed in the plastic encapsulation layer 540 and a conductive material is filled in the contact hole to result in the formation of contact plugs, which are electrically connected to the respective lead-out wires at the bottom and to the semiconductor die at the top. In this embodiment, the contact holes include a first contact hole and a second contact hole, and accordingly, a first contact plug 551 and a second contact plug 552 are formed from filling the conductive material in the first and second contact holes. The first contact plug 551 is electrically connected to the first lead-out wire 531 at the bottom and to the semiconductor die at the top. The second contact plug 552 is electrically connected to the second lead-out wire 532 at the bottom and to the semiconductor die at the top.

It will be recognized that the lead-out wires are provided to enable a flexible arrangement of the connection ports of the control circuit on the back side of the device wafer 100 (for example, they allow the connection ports for connecting the semiconductor die to be located around the lower cavity so that the semiconductor die can be disposed in a central portion of the crystal resonator).

In this embodiment, with reference to FIGS. 2k and 2l, the lead-out wires extend over the respective conductive plugs toward the lower cavity 120 (i.e., a central portion of the device). This allows the semiconductor die 500 to be located close the center of the device during the subsequent bonding of the semiconductor die. In this embodiment, the first lead-out wire 531 extends over the first conductive plug 521 toward the lower cavity 120, and the second lead-out wire 532 extends over the second conductive plug 522 toward the lower cavity 120. The first contact plug 551 is connected to an end of the first wiring layer 531 proximal to the lower cavity 120, and the second contact plug 552 is connected to an end of the second wiring layer 532 proximal to the lower cavity 120.

The semiconductor die may be heterogeneous from the device wafer 100. That is, the semiconductor die may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

Optionally, with reference to FIG. 2m, a second passivation layer 620 may be formed over the device wafer 100, the second passivation layer 620 covers the semiconductor die and the plastic encapsulation layer 540.

It will be appreciated that the second plastic encapsulation layer 620 is provided to cover and protect the thinned side and of the device wafer and all the structures formed thereon. Exemplary materials for the second plastic encapsulation layer 620 may include photoresist.

It is to be noted that, in this embodiment, the successive formation of the piezoelectric vibrator and the cap layer on the front side of the device wafer precedes the bonding of the semiconductor die to the back side of the device wafer. However, in other embodiments, the bonding of the semiconductor die to the back side of the device wafer may precede the successive formation of the piezoelectric vibrator and the cap layer on the front side of the device wafer.

Specifically, according to another embodiment, the method for integrating the crystal resonator with the control circuit may include:

bonding the semiconductor die to the back side of the device wafer and electrically connecting the semiconductor die to the control circuit with the second connecting structure;

forming the second plastic encapsulation layer over the back side of the device wafer, which covers the semiconductor die;

forming the lower cavity of the crystal resonator by etching the device wafer from the front side thereof; and

successively forming the piezoelectric vibrator and the cap layer on the front side of the device wafer and electrically connecting the top and bottom electrodes of the piezoelectric vibrator to the control circuit with the first connecting structure.

A structure for integrating a crystal resonator with a control circuit corresponding to the above method will be described below with reference to FIGS. 2a to 2m. The crystal resonator includes:

a device wafer 100, the control circuit and a lower cavity 120 are formed in the device wafer 100, the lower cavity 120 exposed at a front side of the device wafer, the control circuit including interconnects, at least some of which extend to the front side of the device wafer 100;

a piezoelectric vibrator 200, the piezoelectric vibrator 200 including a top electrode 230, a piezoelectric crystal 220 and a bottom electrode 210, the piezoelectric vibrator 200 formed on the front side of the device wafer 100 and aligned with the lower cavity, the piezoelectric vibrator 200 having peripheral edge portions residing on top edges of the lower cavity 120;

a first connecting structure configured to electrically connect the top and bottom electrodes 230, 210 of the piezoelectric vibrator 200 to the control circuit;

a cap layer 420 formed on the front side of the device wafer 100 so as to hood the piezoelectric vibrator 200, and the cap layer 420 delimits an upper cavity 400 together with the piezoelectric vibrator and the device wafer;

a semiconductor die 500 bonded to a back side of the device wafer 100, wherein in the semiconductor die, there is formed, for example, a drive circuit for producing an electrical signal to be transmitted to the piezoelectric vibrator 200 via the control circuit 100; and

a second connecting structure configured to electrically connect the semiconductor die 500 to the control circuit.

The semiconductor die 500 may be heterogeneous from the device wafer 100. That is, the semiconductor die may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

In this way, the piezoelectric vibrator 200 can be integrated with the control circuit on a single device wafer by forming the lower cavity 120 in the device wafer 100 and forming the cap layer 420 using a semiconductor process, which encloses the piezoelectric vibrator 200 within the upper cavity 400 so that it is ensured that the piezoelectric vibrator 200 can oscillate in the upper and lower cavities 400, 120. In addition, the semiconductor die bonded to the device wafer 100 can enhance performance of the crystal resonator by on-chip modulation under the control of the control circuit 110 for correcting raw deviations of the crystal resonator such as temperature and frequency drifts. Therefore, in addition to an enhanced degree of integration, the crystal resonator of the present invention fabricated using the semiconductor processes is more compact in size and thus less power-consuming.

With continued reference to FIG. 2a, the control circuit may include a first circuit 111 and a second circuit 112, the first circuit 111 and the second circuit 112 may be electrically connected to the top and bottom electrodes of the piezoelectric vibrator 200, respectively.

Specifically, the first circuit 111 may include a first transistor, a first interconnect 111a and a third interconnect 111b. The first transistor may be buried within the device wafer 100, and the first interconnect 111a and the third interconnect 111b may be both connected to the first transistor and extend to the front side of the device wafer 100. The first interconnect 111a may be electrically connected to the bottom electrode 210 and the third interconnect 111b to the semiconductor die.

Similarly, the second circuit 112 may include a second transistor, a second interconnect 112a and a fourth interconnect 112b. The second transistor may be buried within the device wafer 100, and the second interconnect 112a and the fourth interconnect 112b may be both connected to the second transistor and extend to the front side of the device wafer 100. The second interconnect 112a may be electrically connected to the top electrode 230 and the fourth interconnect 112b to the semiconductor die.

In addition, the first connecting structure may include a first connection and a second connection. The first connection may be connected to the first interconnect 111a and the bottom electrode 210 of the piezoelectric vibrator. The second connection may be connected to the second interconnect 112a and the top electrode 230 of the piezoelectric vibrator.

In this embodiment, the bottom electrode 210 is situated on the front side of the device wafer 100 around the lower cavity 120 and the bottom electrode 210 has an extension extending laterally beyond the piezoelectric crystal 220. Additionally, the extension of the bottom electrode covers the first interconnect 111a in the first circuit 111 so as to bring the bottom electrode 210 into electrical connection with the first interconnect 111a in the first circuit 111. Therefore, it can be considered that the extension of the bottom electrode makes up the first connection.

Further, the top electrode 230 is formed on the piezoelectric crystal 220 and the top electrode 230 is electrically connected to the second interconnect 112a in the second circuit 112 via the second connection.

Specifically, the second connection that connects the top electrode 230 to the second circuit 112 may include a conductive plug (e.g., the aforementioned third conductive plug) and an interconnecting wire. The third conductive plug may be formed on the front side of the device wafer 100 in such a manner that it is connected to the second interconnect 112a at the bottom. The interconnecting wire may cover the top electrode 230 at one end and cover, and thus come into connection with, the third conductive plug at the other end. In this way, it will be recognized that the third conductive plug also serves to support the interconnecting wire.

In alternative embodiments, the second connection may include only the conductive plug. In this case, the conductive plug may be electrically connected to the top electrode 230 at one end and to second interconnect 112a at the other end. For example, the top electrode may extend from the piezoelectric crystal over the end of the conductive plug.

In addition, the second connecting structure may include conductive plugs and connecting wires. Each conductive plug may extend through the device wafer 100 so as to be located at the front side of the device wafer 100 at one end and to be located at the back side of the device wafer and electrically connected to the semiconductor die 500 at the other end. The connecting wires may be formed on the front side of the device wafer 100 and connect the respective conductive plugs to the control circuit.

In this embodiment, the conductive plugs of the second connecting structure include a first conductive plug 521 and a second conductive plug 522, and the connecting wires include a first connecting wire 511 and a second connecting wire 512. The first connecting wire 511 connects the first conductive plug 521 to the third interconnect 111b, and the second connecting wire 512 connects the second conductive plug 522 to the fourth interconnect 112b.

In this way, the conductive plugs and connecting wires lead connection ports of the control circuit, to which the semiconductor die is to be electrically connected, from the front to back side of the device wafer. As a result, the semiconductor die is allowed to be arranged on the back side of the device wafer and brought into electrical connection to the control circuit there.

Optionally, the second connecting structure may further include lead-out wires and contact plugs. The lead-out wires may be formed on the back side of the device wafer 100 so as to be connected at one end to the respective conductive plugs. The contact plugs may be electrically connected to the respective lead-out wires at the bottom and to the semiconductor die 500 at the top.

In this embodiment, the lead-out wires of the second connecting structure include a first lead-out wire 531 and a second lead-out wire 532, and the contact plugs include a first contact plug 551 and a second contact plug 552. One end of the first lead-out wire 531 is connected to the first conductive plug 521, and the first contact plug 551 is electrically connected to the other end of the first lead-out wire 531 at the bottom and to the semiconductor die 500 at the top. One end of the second lead-out wire 532 is connected to the second conductive plug 522, and the second contact plug 552 is electrically connected to the other end of the second lead-out wire 532 at the bottom and to the semiconductor die 500 at the top.

The lead-out wires extend over the respective conductive plugs toward the lower cavity 120. In this embodiment, the first lead-out wire 531 extends over the first conductive plug 521 toward the lower cavity 120, and the first contact plug 551 is connected to the end of the first lead-out wire 531 close to the lower cavity 120. In this way, the semiconductor die 500 can be bonded at a location close to the lower cavity 120 and hence to a central portion of the device.

With continued reference to FIG. 2a, in this embodiment, the device wafer 100 includes a substrate wafer 100A and a dielectric layer 100B. The first and second transistors may be both formed on the substrate wafer 100A, and the dielectric layer 100B may reside on the substrate wafer 100A and thus cover both the first and second transistors. Each of the third interconnect 111b, the first interconnect 111a, the fourth interconnect 112b and the second interconnect 112a may be formed in the dielectric layer 100B such as to extend to the surface of the dielectric layer 100B away from the substrate wafer 100A.

With continued reference to FIG. 2m, in this embodiment, at least one opening is formed in the cap layer 400 and closed with a closure plug 430 filled therein. In this way, the piezoelectric vibrator 200 is enclosed within the upper cavity 400.

Furthermore, the crystal resonator may further include a first plastic encapsulation layer 610 formed on the front side of the device wafer 100, which covers an external surface of the cap layer outside the upper cavity 400. In other words, the first plastic encapsulation layer 610 covers all the structures formed on the front side of the device wafer, thus providing protection to the structures underlying the first plastic encapsulation layer 610. The crystal resonator may further include a second plastic encapsulation layer 620 formed on the back side of the device wafer 100, which covers the semiconductor die. It can be considered that the crystal resonator is packaged with the first and second plastic encapsulation layers 610, 620.

In summary, in the method of the present invention, integration of the control circuit with the crystal resonator on a single device wafer is achieved by forming the crystal resonator through forming the lower cavity in, and then the piezoelectric vibrator on, the device wafer containing the control circuit and forming the cap layer using planar fabrication processes, which delimits the upper cavity where the piezoelectric vibrator is enclosed. Additionally, for example, the semiconductor die containing the drive circuit may be further bonded to the device wafer. In other words, the semiconductor die, control circuit and crystal resonator may be integrated on the same device wafer. This is favorable to on-chip modulation for correcting raw deviations of the crystal resonator such as temperature and frequency drifts. Compared with traditional crystal resonators (e.g., surface-mount ones), in addition to being able to integrate with other semiconductor components more easily with a higher degree of integration, the crystal resonator of the present invention that is fabricated using planar fabrication processes is more compact in size and hence less power-consuming. Further, the piezoelectric vibrator of the present invention can be formed on the back side of the device wafer, helping in improving process flexibility of the crystal resonator.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer having the control circuit formed therein;
forming a lower cavity of the crystal resonator in the device wafer by etching the device wafer from a front side thereof;
forming a piezoelectric vibrator comprising a top electrode, a piezoelectric crystal and a bottom electrode on the front side of the device wafer above the lower cavity and forming a first connecting structure, the top and bottom electrodes of the piezoelectric vibrator electrically connecting to the control circuit via the first connecting structure;
forming a cap layer on the front side of the device wafer, the cap layer hooding the piezoelectric vibrator and delimiting an upper cavity of the crystal resonator together with the piezoelectric vibrator and the device wafer; and
bonding a semiconductor die to a back side of the device wafer and forming a second connecting structure, the semiconductor die electrically connecting to the control circuit via the second connecting structure.

2. The method for integrating a crystal resonator with a control circuit of claim 1, wherein the device wafer comprises a substrate wafer and a dielectric layer on the substrate wafer, wherein the lower cavity is formed in the dielectric layer, wherein the substrate wafer is a silicon-on-insulator substrate comprising a base layer, a buried oxide layer and a top silicon layer stacked in sequence from the back side to the front side, and wherein the lower cavity further extends into the buried oxide layer from the dielectric layer.

3. (canceled)

4. The method for integrating a crystal resonator with a control circuit of claim 1, wherein the formation of the piezoelectric vibrator comprises:
forming the bottom electrode at a predetermined location on the front side of the device wafer;
bonding the piezoelectric crystal to the bottom electrode; and
forming the top electrode on the piezoelectric crystal, or comprises:
forming the top and bottom electrodes of the piezoelectric vibrator on the piezoelectric crystal; and bonding the top and bottom electrodes and the piezoelectric crystal as a whole to the front side of the device wafer,
wherein the formation of the bottom electrode comprises a vapor deposition process or a thin-film deposition process, and wherein the formation of the top electrode comprises a vapor deposition process or a thin-film deposition process.

5. (canceled)

6. The method for integrating a crystal resonator with a control circuit of claim 1, wherein the control circuit comprises a first interconnect and a second interconnect and the first connecting structure comprises a first connection and a second connection,
the first connection connecting the first interconnect to the bottom electrode of the piezoelectric vibrator, the second connection connecting the second interconnect to the top electrode of the piezoelectric vibrator.

7. The method for integrating a crystal resonator with a control circuit of claim 6, wherein the bottom electrode is formed on the front side of the device wafer and has an extension extending beyond the piezoelectric crystal thereunder to come into electrical connection with the first interconnect, the extension of the bottom electrode extending beyond the piezoelectric crystal forming the first connection.

8. The method for integrating a crystal resonator with a control circuit of claim 6, wherein the first connection is formed on the device wafer and electrically connected to the first interconnect prior to the formation of the bottom electrode and is electrically connected to the bottom electrode subsequent to the formation of the bottom electrode on the device wafer, wherein the first connection comprises a rewiring layer connected to the first interconnect, and wherein the rewiring layer is electrically connected to the bottom electrode subsequent to the formation of the bottom electrode on the device wafer.

9. (canceled)

10. The method for integrating a crystal resonator with a control circuit of claim 6, wherein the formation of the second connection comprises:
forming a plastic encapsulation layer on the front side of the device wafer;
forming a through hole in the plastic encapsulation layer and filling a conductive material in the through hole, thus resulting in the formation of a conductive plug which has a bottom electrically connected to the second interconnect and has a top exposed from the plastic encapsulation layer;
forming the top electrode on the device wafer so that the top electrode has an extension, which extends beyond the piezoelectric crystal over the top of the conductive plug, thus bringing the top electrode into electrical connection with the conductive plug, or forming the top electrode on the device wafer and an interconnecting wire on the plastic encapsulation layer, which covers the top electrode at one end and covers the conductive plug on the other end; and
removing the plastic encapsulation layer.

11. The method for integrating a crystal resonator with a control circuit of claim 1, wherein the formation of the cap layer delimiting the upper cavity comprises:
forming a sacrificial layer on the front side of the device wafer, which covers the piezoelectric vibrator;
forming a cap material layer over the front side of the device wafer, which warps the sacrificial layer by covering top and side surfaces of the sacrificial layer; and
forming at least one opening in the cap material layer, thus resulting in the formation of the cap layer, and removing the sacrificial layer via the opening in which the sacrificial layer is exposed, thus resulting in the formation of the upper cavity,
after forming the upper cavity, the method further comprising closing the opening in the cap layer to close the upper cavity and thereby enclosing the piezoelectric vibrator within the upper cavity.

12. (canceled)

13. The method for integrating a crystal resonator with a control circuit of claim 1, wherein the formation of the second connecting structure comprises:
forming connecting holes in the device wafer by etching the device wafer from the front side thereof;
forming conductive plugs by filling a conductive material in the connecting holes;
forming connecting wires on the front side of the device wafer, which connect the respective conductive plugs to the control circuit; and
thinning the device wafer from the back side thereof until the conductive plugs are exposed for electrical connection with the semiconductor die, or
wherein the formation of the second connecting structure comprises:
forming connecting wires on the front side of the device wafer, which are electrically connected to the control circuit;
etching the device wafer from the back side thereof so that connecting holes are formed therein, which extend through the device wafer, and in which the respective connecting wires are exposed; and
filling a conductive material in the connecting holes so that conductive plugs are formed, which are connected to the respective connecting wires at one end and for electrical connection with the semiconductor die at the other end.

14. (canceled)

15. The method for integrating a crystal resonator with a control circuit of claim 13, wherein the formation of the second connecting structure further comprises:
forming lead-out wires on the back side of the device wafer, which cover the respective conductive plug;
forming a plastic encapsulation layer over the back side of the device wafer, which covers the lead-out wires; and
forming contact holes in the plastic encapsulation layer and filling a conductive material in the contact holes, thus resulting in the formation of contact plugs, the contact plugs have bottoms electrically connected to the respective lead-out wires and tops electrically connected to the semiconductor die, and
wherein the bonding of the semiconductor die is accomplished by bonding the semiconductor die to the plastic encapsulation layer and electrically connecting the semiconductor die to the tops of the contact plugs.

16. The method for integrating a crystal resonator with a control circuit of claim 1, further comprising: forming a first plastic encapsulation layer over the front side of the device wafer, which covers the front side of the device wafer and an external surface of the cap layer outside the upper cavity, subsequent to the formation of the cap layer and prior to the bonding of the semiconductor die; and
forming a second plastic encapsulation layer over the back side of the device wafer, which covers the semiconductor die, subsequent to the bonding of the semiconductor die.

17. The method for integrating a crystal resonator with a control circuit of claim 1, wherein the successive formation of the piezoelectric vibrator and the cap layer on the front side of the device wafer precedes the bonding of the semiconductor die to the back side of the device wafer, or wherein
the bonding of the semiconductor die to the back side of the device wafer precedes the successive formation of the piezoelectric vibrator and the cap layer on the front side of the device wafer.

18. A structure for integrating a crystal resonator with a control circuit, comprising:
a device wafer in which the control circuit and a lower cavity are formed, the lower cavity exposed from a front side of the device wafer;
a piezoelectric vibrator comprising a top electrode, a piezoelectric crystal and a bottom electrode, the piezoelectric vibrator formed on the front side of the device wafer and aligned with the lower cavity;
a first connecting structure configured to electrically connect the top and bottom electrodes of the piezoelectric vibrator to the control circuit;
a cap layer formed on the front side of the device wafer, the cap layer hooding the piezoelectric vibrator and delimiting an upper cavity together with the piezoelectric vibrator and the device wafer;
a semiconductor die bonded to a back side of the device wafer; and
a second connecting structure configured to electrically connect the semiconductor die to the control circuit.

19. The structure for integrating a crystal resonator with a control circuit of claim 18, wherein the device wafer comprises a substrate wafer and a dielectric layer on the substrate wafer, wherein the lower cavity is formed in the dielectric layer, wherein the substrate wafer is a silicon-on-insulator substrate comprising a base layer, a buried oxide layer and a top silicon layer stacked in sequence from the back side to the front side, and wherein the lower cavity further extends into the buried oxide layer from the dielectric layer.

20. (canceled)

21. The structure for integrating a crystal resonator with a control circuit of claim 18, wherein the control circuit comprises a first interconnect and a second interconnect and the first connecting structure comprises a first connection and a second connection,
the first connection connecting the first interconnect to the bottom electrode of the piezoelectric vibrator, the second connection connecting the second interconnect to the top electrode of the piezoelectric vibrator.

22. The structure for integrating a crystal resonator with a control circuit of claim 21, wherein the bottom electrode is formed on the front side of the device wafer and has an extension extending beyond the piezoelectric crystal to come into electrical connection with the first interconnect, the extension of the bottom electrode extending beyond the piezoelectric crystal forming the first connection.

23. The structure for integrating a crystal resonator with a control circuit of claim 21, wherein the second connection comprises a conductive plug which is electrically connected to the top electrode at one end and to the second interconnect at the other end, or
wherein the second connection comprises:
a conductive plug, which is formed on the front side of the device wafer and has a bottom electrically connected to the second interconnect; and
an interconnecting wire covering the top electrode at one end and covering a top of the conductive plug at the other end, thereby connecting the interconnecting wire with the conductive plug.

24. (canceled)

25. The structure for integrating a crystal resonator with a control circuit of claim 18, wherein the second connecting structure comprises:
conductive plugs, which extend through the device wafer so that the conductive plugs are each located at the front side of the device wafer at one end and are located at the back side of the device wafer and electrically connected to the semiconductor die at the other end;
connecting wires formed on the front side of the device wafer, the connecting wires connecting the respective conductive plug to the control circuit;
lead-out wires formed on the back side of the device wafer and connected at one end to the respective conductive plugs; and
contact plugs have bottoms electrically connected to the other ends of the respective lead-out wires and tops electrically connected to the semiconductor die.

26. (canceled)

27. The structure for integrating a crystal resonator with a control circuit of claim 18, wherein at least one opening is formed in the cap layer and closed with a closure plug filled therein, thus enclosing the upper cavity.

28. The structure for integrating a crystal resonator with a control circuit of claim 18, further comprising:
a first plastic encapsulation layer formed on the front side of the device wafer, which covers an external surface of the cap layer outside the upper cavity; and
a second plastic encapsulation layer formed on the back side of the device wafer, which covers the semiconductor die.
